(19) United States
(12) Patent Application Publication
(10) Pub. No.: US 2006/0031733 A1
(43) Pub. Date: Feb. 9, 2006

(54) Power-saving retention mode

(76) Inventors: Xiaowei Zhu, Plano, TX (US); Claude R. Cirba, Plano, TX (US)

Correspondence Address: TEXAS INSTRUMENTS INCORPORATED, P O BOX 655474, M/S 3999, DALLAS, TX, 75265, US

(21) Appl. No.: 10/910,440

(22) Filed: Aug. 3, 2004

(51) Int. Cl. G01R 31/30; G06F 11/00

(52) U.S. Cl. 714/745

(57) ABSTRACT

Embodiments of the invention are disclosed wherein methods and systems are provided for implementing a power-saving retention mode in an integrated circuit having both logic elements and memory elements. The methods of the invention include steps for scanning at least some of the logic elements of the integrated circuit and writing the states of the scanned logic elements to memory elements. Upon entering a retention mode, the scanned logic elements of the integrated circuit are powered down to conserve power. Transitioning from retention mode to active mode, the logic elements of the integrated circuit are again powered up and the scanned logic states are restored to the logic elements from the memory elements. Also disclosed is the implementation of the invention in combination with known power-saving techniques.

### TECHNICAL FIELD

The invention relates in general to electronic circuitry. More particularly, it relates to integrated circuit (IC) systems providing both logic and embedded memory functionality. The methods and systems of the invention relate more specifically to the reduction of power consumption in ICs using embedded memory.

### BACKGROUND OF THE INVENTION

Power conservation in electronic circuitry has long been a concern in the electronic arts. Particularly in applications using battery power, such as portable electronic systems and backup systems, power conservation can be a significant design consideration. Various techniques exist in the arts to attempt to reduce power consumption in ICs, including but not limited to the use of a “sleep” mode during which power is temporarily turned off or reduced. It has long been known in the arts to turn off circuitry during periods of non-use in order to conserve power. Loss of data and the necessity for rebooting system circuitry for renewed use are problems that accompany such an approach. Various approaches to the problem include some type of “retention” mode used to retain system information in memory during periods of non-use. One such approach is the dynamic control of voltage levels according to which an operational voltage level, for example 1.2 V, may be used for an active mode for circuit operation and a reduced voltage level, for example 0.7 V, may be used for a retention mode. The reduced voltage level used in such a scheme is sufficient for preserving the content of system memory elements. For operations performed with data in memory, the voltage is returned to the higher active mode level. Another power conservation technique known in the arts is back-biasing the transistors of an IC during a retention mode. Such an approach introduces a back-biasing voltage to the chip substrate in order to reduce current leakage from circuit logic and memory elements, e.g. transistors, used to retain logic settings and data.

As microelectronic circuits utilize increasing numbers of transistors, limiting power consumption generally becomes increasingly difficult due to the more numerous paths for current leakage. The desire for increased portability also demands smaller batteries, making power conservation that much more important. Due to these and other problems, improved systems and methods for power conservation in IC systems would be useful and desirable in the arts.

### SUMMARY OF THE INVENTION

In carrying out the principles of the present invention, in accordance with preferred embodiments thereof, methods and systems for power conservation in ICs using a retention mode are provided.

According to one aspect of the invention, methods for retaining logic states in an integrated circuit having both logic elements and memory elements include steps for scanning at least some of the logic elements of the integrated circuit and writing the states of the scanned logic elements to memory elements. Upon entering a retention mode, the scanned logic elements of the integrated circuit are powered down to conserve power. Transitioning from retention mode to active mode, the logic elements of the integrated circuit are again powered up and the scanned logic states are restored to the logic elements from the memory elements where they had been stored.

According to another aspect of the invention, the retention mode techniques are performed in combination with steps for dynamically controlling integrated circuit voltage levels.

According to yet another aspect of the invention, the retention mode techniques are performed in combination with steps for conserving power by back-biasing one or more portions of the integrated circuit.

According to additional aspects of the invention, internal scanning capabilities of an IC are used to implement transitions between an active mode and a retention mode.

According to still another aspect of the invention, system embodiments are disclosed in which an integrated circuit includes means for scanning logic elements of the integrated circuit and for writing the states of the scanned logic elements to memory elements of the integrated circuit. Means are also provided for powering down the scanned logic elements of the integrated circuit, and subsequent to a power-saving interval, rewriting the scanned logic states from the memory elements to the logic elements, then powering up the logic elements.

The invention provides advantages including but not limited to power conservation in ICs, low cost implementation with existing IC designs, flexible implementation for selected logic blocks within circuitry, and implementation in combination with alternative power conservation techniques. These and other features, advantages, and benefits of the present invention can be understood by one of ordinary skill in the arts upon careful consideration of the detailed description of representative embodiments of the invention in connection with the accompanying drawings.

### BRIEF DESCRIPTION OF THE DRAWINGS

The present invention will be more clearly understood from consideration of the following detailed description and drawings in which:

FIG. 1 is a simplified block diagram depicting an example of preferred embodiments of systems and methods of the invention;

FIG. 2 is a simplified block diagram illustrating an example of the system and flow of steps used in preferred methods of the invention; and

FIG. 3 is a simplified block diagram further illustrating an example of the system and flow of steps used in preferred methods of the invention.

References in the detailed description correspond to like references in the figures unless otherwise noted. Descriptive and directional terms used in the written description such as first, second, top, bottom, upper, side, etc., refer to the drawings themselves as laid out on the paper and not to physical limitations of the invention unless specifically noted. The drawings are not to scale, and some features of embodiments shown and discussed are simplified or amplified for illustrating the principles, features, and advantages of the invention.

### DETAILED DESCRIPTION OF PREFERRED EMBODIMENTS

In general, the invention provides methods and systems for implementing a power-saving retention mode in an IC. It has been observed that ICs generally include scanning capabilities used for testing purposes. The methods and systems of the invention utilize these capabilities for scanning, retaining, and rewriting logic states in a novel approach to providing a retention mode.

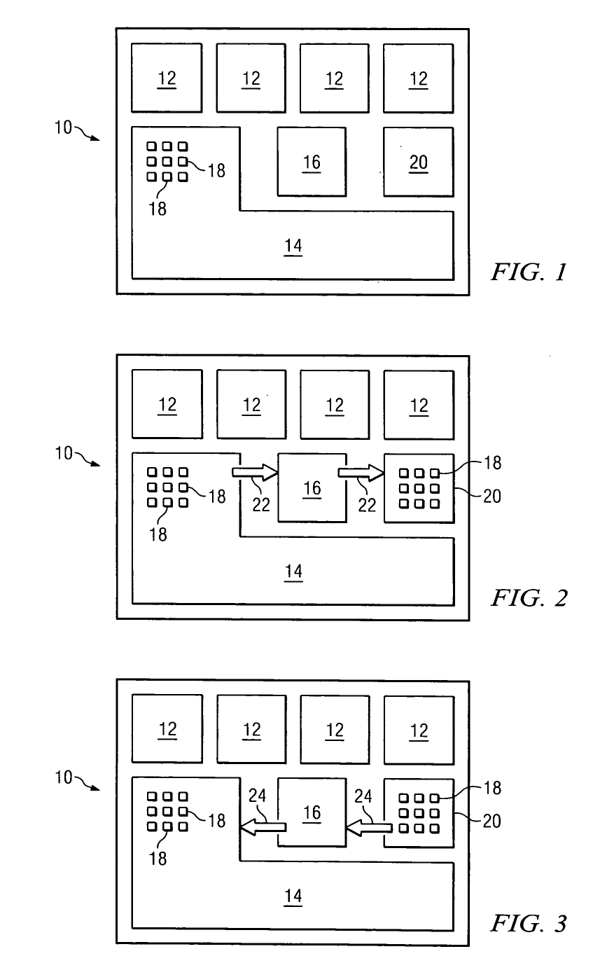

Referring primarily to FIG. 1, an IC 10 includes blocks of memory elements 12 and logic circuitry 14. The IC 10 also includes internal scanning capabilities, represented by block 16. Internal scanning circuitry is familiar in the arts in the context of providing test capabilities in complex ICs. Preferably, the internal scanning circuitry 16 used in implementing the invention includes common scanning circuitry suitably adapted for operation as described herein. Internal scanning functionality known in the arts, such as boundary scan capabilities may be used. Logic states are represented in the figures by the small boxes 18 within the logic circuitry 14. Also indicated in FIG. 1, a memory block 20 is arbitrarily selected for the purposes of example to indicate a particular sub-element of memory blocks 12. Those skilled in the arts will understand that the Figures represent a high-level conceptual view of the systems and methods of the invention and that the invention may be implemented using various alternative configurations of hardware, software and firmware.

Now referring primarily to FIG. 2, a memory block 20, for example comprised of SRAM cells, is selected and cleared prior to placing the IC 10 into a retention mode. Also prior to placing the IC 10 into retention mode, all or a portion of the logic circuit 14 is scanned, preferably using the internal scanning capabilities 16 of the IC 10, and the selected memory block 20 is used to retain the scanned logic states 18. It should be appreciated by those skilled in the arts that the scanning circuitry 16 generally included in ICs for testing purposes may be adapted by adding scan controlling means to perform the scanning functions contemplated for use in implementing the invention without undue experimentation. The scanning and retention of the logic states 18 is represented in FIG. 2 by arrow path 22.

Subsequent to storing the logic state 18 of scanned logic elements 14 of the chip 10 in memory 20, the chip 10 may be placed into a retention mode. Preferably, in retention mode, the memory blocks 12 of the chip are placed into a power-conserving state such as reduced power, or in the case of non-volatile memory, may be powered down. Preferably, the scanned logic portion 14 of the IC 10 is powered down in order to provide maximum power conservation. It should be understood that the invention may be applied to either all or a selected portion of the logic circuitry of an IC, depending upon the needs of the particular application. It has been found that depending upon the relative proportions of logic elements to memory elements in an IC, from approximately one-half to three-quarters of power consumption due to leakage current may be attributed to the logic circuitry. Thus, by facilitating the shut-down of logic circuitry, the invention provides significant advantages in reducing power consumption due to current leakage.

Now referring primarily to FIG. 3, in preparation for returning the chip 10 to an active mode, the memory block 20 is read, again preferably by the internal scanning circuitry 16, and the scanned logic states 18 are rewritten back into the appropriate logic circuitry 14. This progression is indicated by arrow path 24. Subsequently, the chip 10 is returned to an active operational mode. Of course, those skilled in the arts will perceive that various power conservation schemes known in the arts may be used in combination with the invention without departure from the principles and practice of the invention and that various means for implementing the principles of the invention may be derived within the framework of the invention.

The methods and devices of the invention provide advantages including but not limited to improved power conservation in ICs, low cost implementation with existing IC designs, flexible implementation for selected logic blocks within ICs, reduced current leakage, and compatibility for implementation in combination with commonly used complementary power conservation techniques. While the invention has been described with reference to certain illustrative embodiments, the methods and systems described are not intended to be construed in a limiting sense. Various modifications and combinations of the illustrative embodiments as well as other advantages and embodiments of the invention will be apparent to persons skilled in the art upon reference to the description and claims.

We claim:

1. A method for retaining logic states in an integrated circuit having a plurality of logic elements and a plurality of memory elements, the method comprising the steps of:
scanning a plurality of the logic elements of the integrated circuit;
writing the states of the scanned logic elements to memory elements of the integrated circuit;
powering down the scanned logic elements of the integrated circuit, thereby conserving power;
powering up the scanned logic elements of the integrated circuit; and
writing the scanned logic states from the memory elements to the logic elements.

2. A method according to claim 1 further comprising the step of scanning the memory elements using internal scanning capabilities of the integrated circuit.

3. A method according to claim 1 wherein the steps are performed for selected logic blocks of the integrated circuit.

4. A method according to claim 1 wherein the steps are performed for all logic blocks of the integrated circuit.

5. A method according to claim 1 wherein the steps are performed in combination with steps for conserving power by dynamically controlling integrated circuit voltage levels.

6. A method according to claim 1 wherein the steps are performed in combination with steps for conserving power by back-biasing one or more portions of the integrated circuit.

7. In an integrated circuit having a plurality of logic elements and a plurality of memory elements, a system for retaining logic states comprising means for:
scanning a plurality of logic elements of the integrated circuit;
writing the states of the scanned logic elements to memory elements of the integrated circuit;
powering down the scanned logic elements of the integrated circuit, thereby conserving power;
powering up the scanned logic elements of the integrated circuit; and
writing the scanned logic states from the memory elements to the logic elements.

8. A system according to claim 8 wherein the means for scanning the memory elements further comprise internal scanning means of the integrated circuit.
